(19) United States
(12) Patent Application Publication
(10) Pub. No.: US 2007/0235072 A1
(43) Pub. Date: Oct. 11, 2007

(54) Solar cell efficiencies through periodicity

(76) Inventors: Peter Bermel, Cambridge, MA (US); John D. Joannopoulos, Belmont, MA (US); Chiyan Luo, Woodside, NY (US)

Correspondence Address: GAUTHIER & CONNORS, LLP, 225 FRANKLIN STREET, SUITE 2300, BOSTON, MA, 02110, US

(21) Appl. No.: 11/400,911

(22) Filed: Apr. 10, 2006

(51) Int. Cl. H01L 31/00

(52) U.S. Cl. 136/252

(57) ABSTRACT

A solar cell includes a photovoltaic material region. The photovoltaic material region is covered by a uniform anti-reflection coating. A photonic crystal structure is positioned on the photovoltaic material region. The photonic crystal structure provides a medium to produce a plurality of spatial orientations of an incident light signal received by the solar cell so as to allow trapping of a selective frequency of incident light in the solar cell.

### BACKGROUND OF THE INVENTION

The invention relates to the field of solar cells, and in particular using micro photonic crystals in a solar cell design to significantly enhance the absorption efficiency over certain frequencies.

Sunlight has long been recognized as a long-lasting, low-impact and clean energy source. To capture the energy in sunlight, semiconductor solar cells have been designed to convert photons with energy greater than or equal to the semiconductor bandgap energy into electricity. One of the most widely used solar cell material is crystalline silicon (Si), whose bandgap at room temperature correspond to photons with wavelength λ=1.1 μm and is useful for a large portion of the solar spectrum. However, due to the indirect bandgap of Si, its absorption is strong only when the incident wavelength is well below λ_{G}, and becomes fairly weak for long wavelengths, with an absorption length of over 10 μm for X=0.8 μm and an absorption length over 1 mm for λ=1.1 μm, as shown in FIG. 1A. However, this part of the solar spectrum contains 22.7% of the available power, as illustrated in FIG. 1B.

As a result of this property of Si, a 10 μm-thick Si micro solar cell will primarily absorb wavelengths λ=0.8 μm and below, while wavelengths between 0.8 μm and 1.1 μm (=λ_{G}) are mostly lost to reflection. It would certainly be very desirable to improve the design of these Si micro solar cells so that they can not only use less Si material but also remain an effective absorber for all the photons with energies greater than the Si bandgap.

### SUMMARY OF THE INVENTION

According to one aspect of the invention, there is provided a solar cell. The solar cell includes a photovoltaic material region. The photovoltaic material region is covered by a uniform anti-reflection coating. A photonic crystal structure is positioned on the photovoltaic material region. The photonic crystal structure provides a medium to produce a plurality of spatial orientations of an incident light signal received by the solar cell so as to allow trapping of a selective frequency of incident light in the solar cell.

According to another aspect of the invention, there is provided a method of forming a solar cell. The method includes a photovoltaic material region, and forming a uniform anti-reflection coating on top. Also, the method includes forming a photonic crystal structure that is positioned on the photovoltaic material region. The photonic crystal structure provides a medium to produce a plurality of spatial orientations of an incident light signal received by the solar cell so as to allow trapping of a selective frequency of incident light in the solar cell.

According to another aspect of the invention, there is provided a solar cell. The solar cell includes a photovoltaic material region. The photovoltaic material region has a planar top surface, and a uniform anti-reflection coating is positioned on top of the photovoltaic material region. A photonic crystal structure surrounds a portion of the photovoltaic material region. The photonic crystal structure provides a medium to produce a plurality of spatial orientations of an incident light signal received by the solar cell so as to allow trapping of a selective frequency of incident light in the solar cell.

According to another aspect of the invention, there is provided a method of forming a solar cell. The method includes providing a photovoltaic material region with a planar top surface, and forming a uniform anti-reflection coating which is positioned on top of the photovoltaic material region. Also, the method includes forming a photonic crystal structure surrounding a portion of the photovoltaic material region. The photonic crystal structure provides a medium to produce a plurality of spatial orientations of an incident light signal received by the solar cell so as to allow trapping of a selective frequency of incident light in the solar cell.

### BRIEF DESCRIPTION OF THE DRAWINGS

FIG. 1A is a graph demonstrating the absorption coefficient in Si below 1.5 μm;

FIG. 1B is a graph demonstrating the spectrum of the solar power and the corresponding photon number flux;

FIGS. 2A-2B are schematic diagrams illustrating a comparison between one solar cell arrangement and the inventive solar cell arrangement;

FIGS. 3A-3D are graphs demonstrating reflections of a TE waves in a 10 λ-thick at normal incidence and the relative intensity of the spectral reflection components; and

FIGS. 4A-4B are schematic diagrams of other embodiments of the invention.

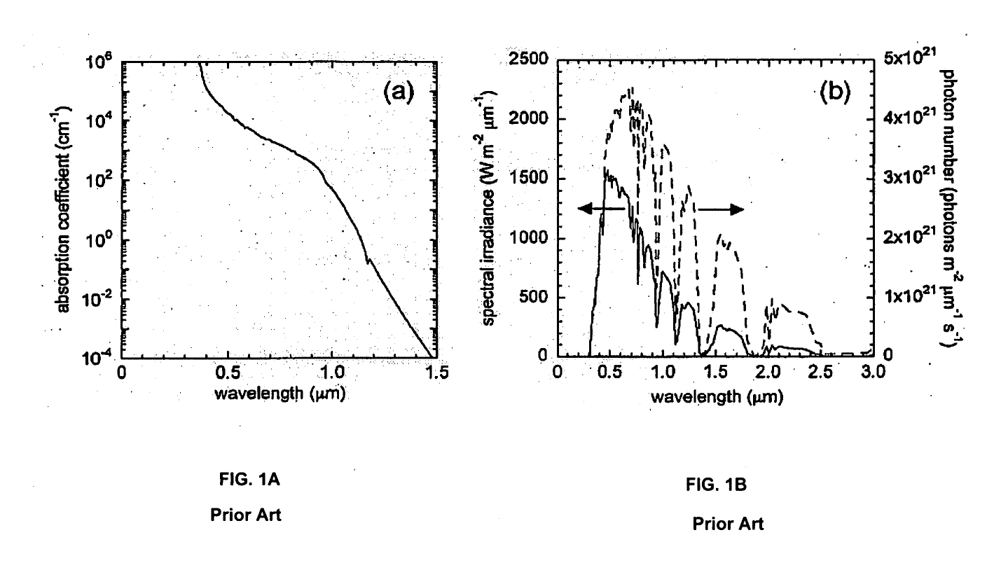

### DETAILED DESCRIPTION OF THE INVENTION

The invention introduces micro photonic crystals into a solar cell design. One can show that there exist several new mechanisms in the photonic-crystal based solar cell designs which can significantly enhance the absorption efficiency over certain wavelengths. This range of wavelengths can then be designed to be near λ_{G} to capture photons that have thus far been neglected in conventional thin-film solar cells made of indirect bandgap semiconductors, e.g., silicon.

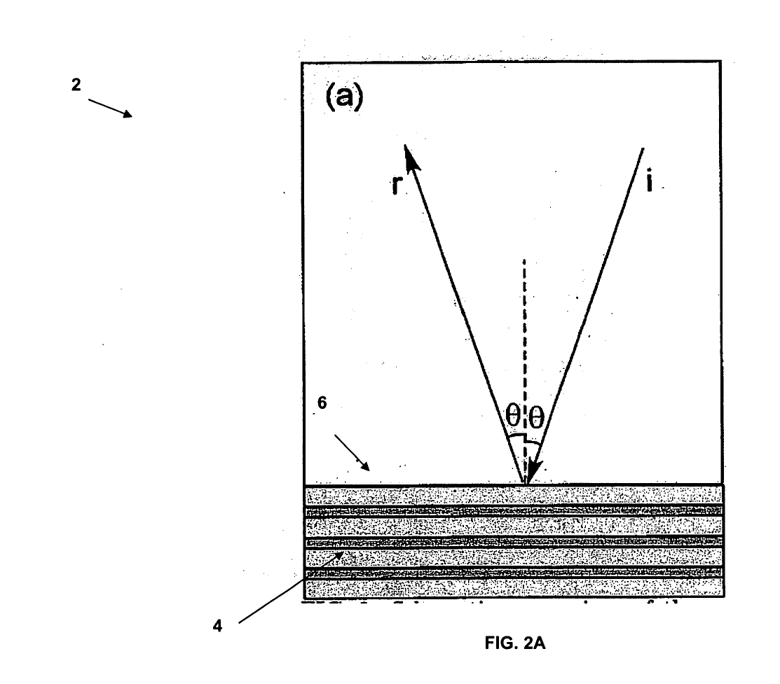

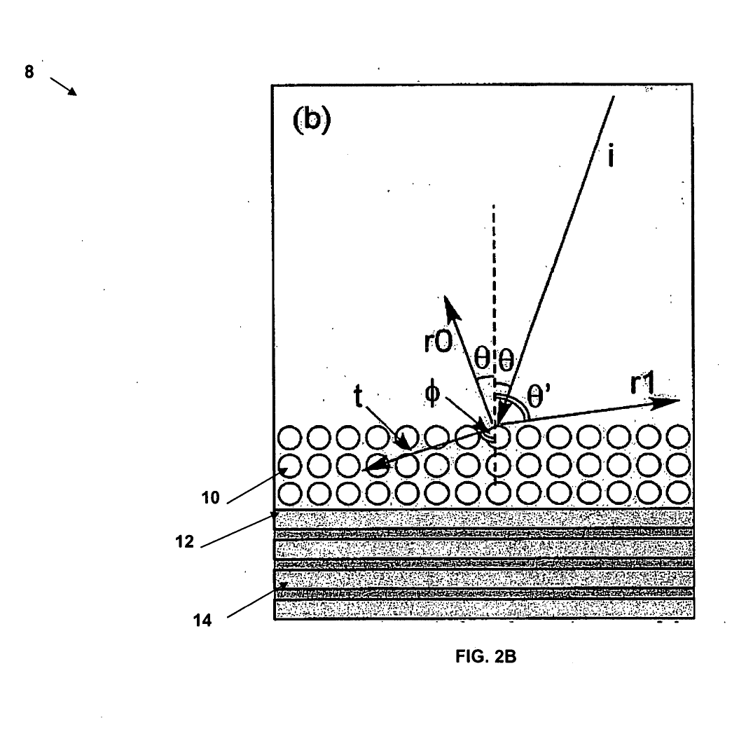

The key in improving the absorption efficiency of a photovoltaic material layer lies in methods to increase the light path length inside the layer. For simplicity, the interface with air is temporarily ignored; light propagation is considered within the photovoltaic cell only. FIG. 2A shows a solar cell design 2 having a photovoltaic material layer 6 of thickness d with a distributed Bragg reflector or photonic crystal (DBR) 4 at the bottom. For such a photovoltaic material layer 6 the path length for light traveling with a propagation angle θ, for example, the angle of the wavevector of the light to the DBR surface normal, is roughly L=2d/cos θ. It is clear that a large θ is beneficial for a long path and better absorption. In conventional solar cell designs, however, θ is usually fixed by the angle of incidence to the device 2, and the reflection off the DBR does not change θ. In this embodiment, the photovoltaic material layer comprises Si, however, other indirect bandgap semiconductors can be used. Note the a photonic crystal can be used in another embodiment in place of the DBR 14.

The situation changes if one introduces an “air-hole” type photonic crystal structure 10 in the photovoltaic material 12 above the bottom DBR 14, as depicted in FIG. 2B. An incident ray i is reflected into channel r0 (spectral direction), diffracted into channels r1, etc., and refracted into channel t within the photonic crystal structure 10. Consequently, several propagation angles, such as θ, θ′, and φ are possible in the photonic-crystal based design. On the photonic-crystal/DBR interface 12, the incident light should be almost entirely reflected back into the photonic crystal 10, as long as the DBR is designed properly for the range of frequencies expected to reach it (typically 0.7 μm to 1.1 μm in silicon). The photonic crystal structure 10 can include 1D, 2D, and 3D photonic crystals. Moreover, these photonic crystal structures can be comprised of holes made of air or dielectric, a periodically etched grating on the DBR 14, or alternating layers of high and low indexes with periodicity parallel to the surface.

For the reflected beams, due to the surface periodicity, the direction of propagation can now be in all the diffraction directions that have wavevectors differing from the usual spectral-reflection wavevector by a reciprocal lattice vector. Thus it is possible to change the propagation angles in the photovoltaic material region by exploiting the diffracted reflection beams. For example, a portion of energy in the beam of small incident θ can be diverted into beams of large reflected θ′, which is then absorbed more effectively. Furthermore, if the interface with air is now considered, it is evident that sufficiently oblique angles will lead to total internal reflection, which traps light very strongly. A model for the orientation of the diffracted beams can be constructed, which shows that frequencies within a range from cG/n to cG, which are diffracted, should subsequently be internally reflected, where c is the speed of light, G is the reciprocal lattice vector, and n is the refractive index of the photovoltaic material. For a high index (e.g., n=3.5 in Si in near-infrared), this is a sufficiently large range to internally reflect the entire range of target wavelengths (0.7 μm to 1.1 μm in Si), provided enough resonances are present. However, clearly for a solar cell with a small number of resonances in this range, because of a very low absorption coefficient or a very thin layer of material, leakage back into air at the intermediate frequencies will limit the performance of this device.

For the refracted beams, large angles of refraction can also occur for certain angles of incidence, for example, in the superprism effect. The refracted angle into the photonic crystal can be found by first calculating the constant-frequency contours of the photonic crystal, then choosing the mode(s) that conserve both frequency and the parallel component of the wavevector (up to a reciprocal lattice vector). The condition for large propagation angles is that gradient vectors generated from the constant-frequency surfaces, which represent the direction of the group velocity, make a large angle with the surface normal. In practical designs, the DBR reflects back all the refracted photonic crystal modes. The light in these modes ultimately gets absorbed or re-enters the photovoltaic material. The final propagation directions are thus only those determined from surface diffraction, though the strength of each diffracted beams depends on its coupling to the corresponding photonic crystal mode. The presence of the DBR also means that the photonic crystal region is finite and can therefore admit resonances. These resonances are also beneficial for light absorption because light can also bounce back and forth inside the photonic crystal and become gradually absorbed. Furthermore, these resonances are especially important for the photonic-crystal modes with large angles of refraction. As has been shown in previous work, these super-refracted modes would be difficult to couple to without resonances. On the other hand, one can expect that on resonances these super-refracted modes are absorbed well because they have difficulty escaping the photonic crystal layer. In summary, a photonic-crystal based photovoltaic cell can have anomalous reflection and refraction properties, including total internal reflection, and can also form photonic crystal resonances for incident light, all of which can be used to improve the absorption efficiency of a thin photovoltaic cell.

In order to illustrate the enhancement of absorption efficiency for photonic-crystal based designs, S-matrix calculations are performed on a simple 2D system: a photovoltaic material layer, 104 thick in total, with 3 periods of a square lattice air-columns of (10) surface termination at the bottom. The lattice period α is then taken to be α=0.254 and the column radius is chosen to be 0.4α. For simplicity, perfect metal is used in place of the DBR, the dielectric constant of the photovoltaic material layer is taken to be a constant ε=12+0.0033i, the light is assumed to come from either the same photovoltaic material region or air above it, and is polarized perpendicular to the column axis, corresponding to TE modes. This ε corresponds to an absorption length of 167 λ₀ at wavelength which λ₀ absorbs 11% of light with only a reflector (but no photonic crystal) present.

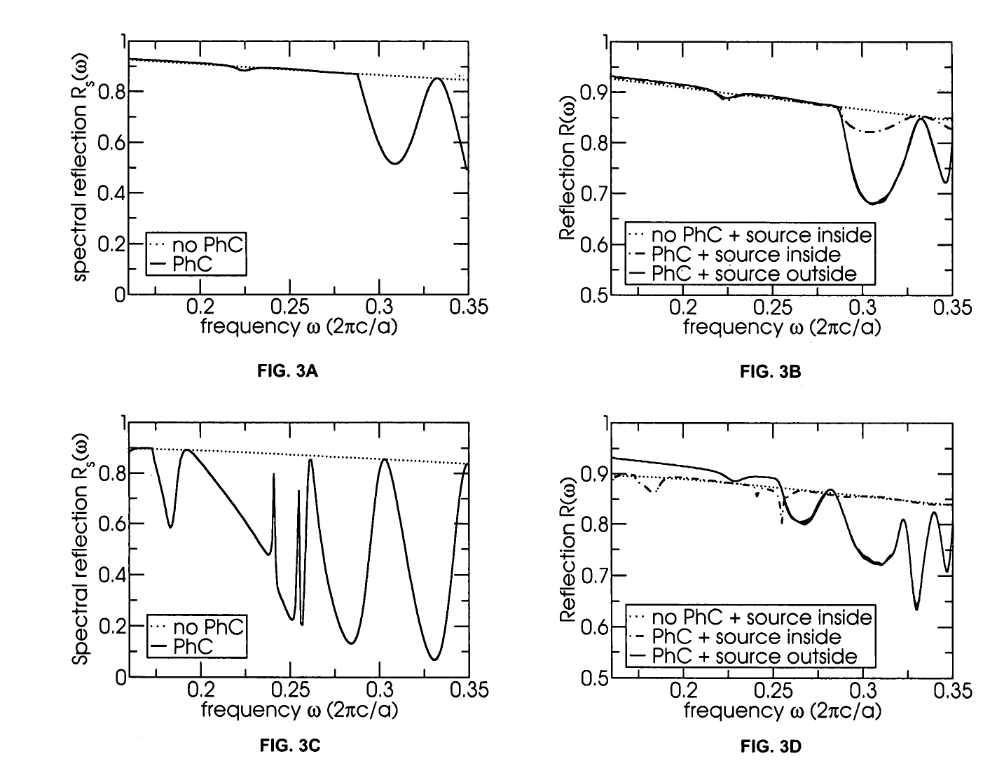

Both normal incidence and incidence at an angle on the system are considered, and two kinds of reflection coefficients are calculated to measure the strength of absorption, as shown in FIGS. 3A-3D. FIGS. 3A and 3C are graphs demonstrating “spectral reflection” that is used to denote the relative power remaining in the spectrally reflected beam, and FIGS. 3B and 3D are graphs demonstrating “overall reflection” that is used to represent the total relative power carried by all reflected waves.

For the normal incidence case, FIG. 3A shows a significant amount of light can be transferred to the ±1 diffraction channels when the frequency is larger than the diffraction threshold, which is seen as the difference between the dotted line (representing no photonic crystal), and the solid line (representing a photonic crystal with the parameters discussed above). In particular, near ω=0.309·2πc/α, there is a peak of energy lost to highly oblique diffraction. FIG. 3B shows the overall reflection for two cases: one with a source contained in silicon, and one with a source in air, above the silicon, which has a uniform anti-reflection coating on the top. The reflection for the latter case is smoothed out to suppress the physically uninteresting Fabry-Perot oscillations of this system. Also, the anti-reflection coating substantially decreases Fresnel reflection at the high index-contrast interface between silicon and air. The anti-reflection coating must be uniform to ensure good coupling into the photovoltaic material throughout the entire region exposed to light. Referring to FIG. 3B now, clearly more absorption takes place for the case of a source in air. Physically, this comes about because the anti-reflection coating couples light into the photovoltaic material and then total internal reflection strongly confines oblique modes to the photovoltaic material region until they are absorbed, as discussed previously. However, the light is still not completely absorbed because some potentially diffracted light leaks into the spectral modes (which are reflected out of the cell).

The case of incidence at an angle is numerically implemented as a transverse wavevector 0.4·2π/α in the S-matrix calculation. In this case, the diffraction threshold frequency is much lower, and more drastic behavior can be seen in the spectral reflections. For example, the spectral component can go to less than 7% at ω=0.331·2π/α. The major portion of the energy at this frequency is negatively-reflected at an angle of around 30° for an incidence angle of 20°. Also, note that a sharp dip occurs in FIG. 3C at ω=0.255·2πc/α. Since it can be seen also in the overall reflection in FIG. 3D, it means strong absorption occurs at ω=0.255·2πc/α for all diffraction beams, and therefore represents a strong coupling to a super-refraction resonance in the photonic crystal. In this case, the frequency is in the second photonic band, whose contour is known to have flat edges perpendicular to the interface and can thus produce super-reflections. In summary, the surface diffraction, total internal reflection, and resonances in the photonic crystal layer have all been observed to significantly reduce the spectral-reflected beam intensity. Although the overall reflection is higher for the case of a source inside the solar cell, coupling out of the spectral direction is the most important factor for solar cell applications.

For simplicity many of the reflection properties of a 2D photonic-crystal based absorptive layer have been considered for the case when the incident medium is the same as the photovoltaic material (except for the last curve in both FIGS. 3B and 3D). Of course, any real photovoltaic cell must have an interface with air that in general need not be flat. In fact, the idealized Lambertian surface is known to be able to couple incident light from air into the photovoltaic material with propagation angles larger than θ_{c}, the critical angle for total internal reflection. However, in both the planar and the Lambertian surface geometries, symmetry means that the spectrally reflected beam usually can escape the structure easily. As a result, there is a fixed upper limit to the absorption enhancement of the Lambertian geometry relative to the flat cell, given by 2n², where n is the refractive index of the photovoltaic material region.

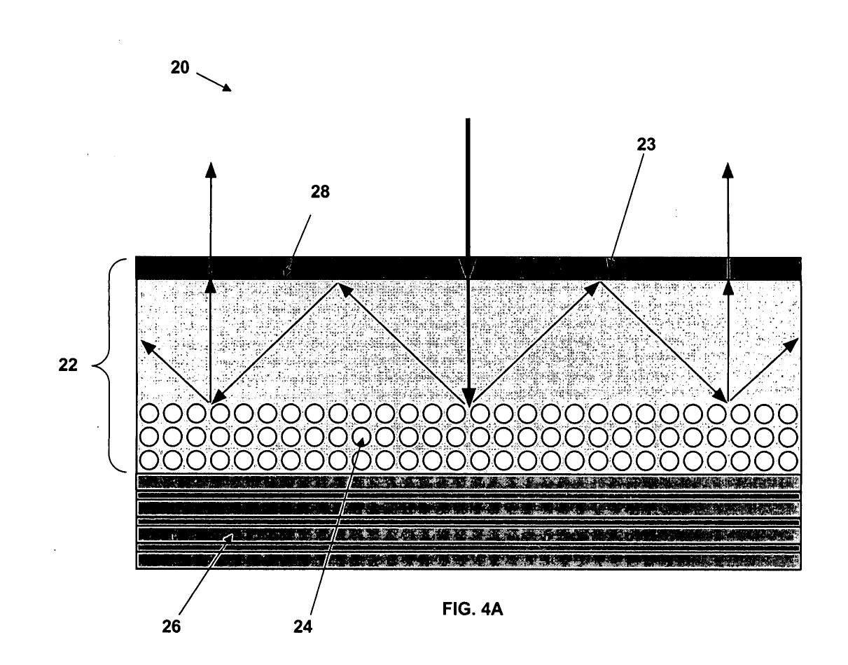

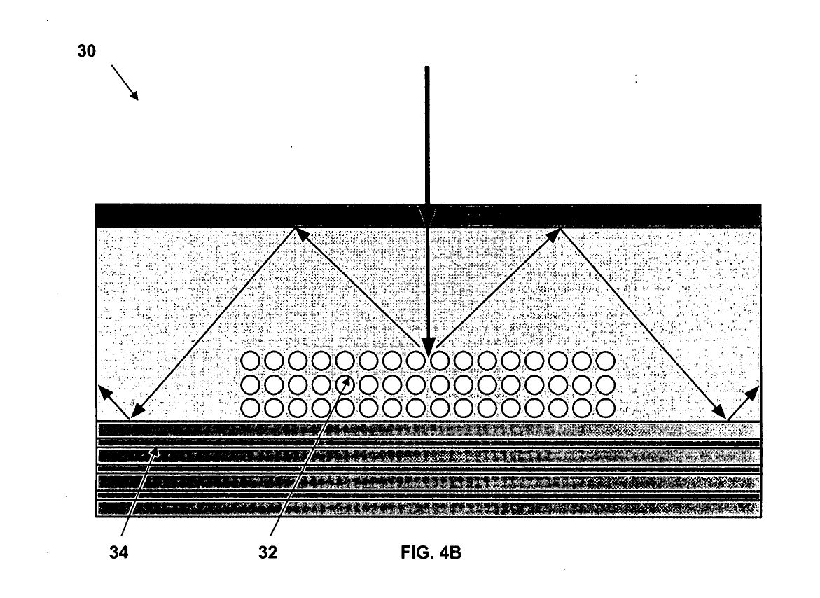

On the other hand, the photonic-crystal based solar cells trap light using a different principle, which is capable of greatly exceeding this limit for some frequencies. In the planar air/anti-reflection coating/Si case, possible solar cell designs using the reduced spectral reflection are shown in FIG. 4A-4B. FIG. 4A shows a solar cell arrangement 20 having a planar region 22 for trapping light comprising an anti-reflection coating Si 23 and a photonic crystal 24 surrounding the entire region of a bottom reflector 26. Note the bottom reflector can be a DBR or a similar reflector. Moreover, FIG. 4A shows the propagation of beams when the ±1 diffraction angle is large enough for total internal reflection on the top Si surface 28, which can increase the optical path length significantly. It is noteworthy that even if the power transfer to diffraction beams were perfect, there could still be some power leaking back into air, because diffracted modes could be coupled back into spectral modes. These photonic crystal structures can be comprised of holes of air or dielectric materials, or alternating high and low index layers with periodicity parallel to the surface of the solar cell.

FIG. 4B shows a solar cell arrangement 30 similar to the solar cell arrangement 20 of FIG. 4A, except the photonic crystal 32 does not cover the entire bottom reflector 34. The design in FIG. 4B creates a truly guided mode from incident beams, preventing coupling back into spectral modes; but the cost is the reduction in useful area covered by photonic crystals. Similar designs involving the Lambertian surface structures are also possible, but can decrease the quality factor of the mode substantially, leading to greater reflection losses. It is clear that only the spectrally-reflected beam intensity needs to be considered in high efficiency photonic-crystal based solar cells. Nevertheless, the super-refraction effect enhanced by resonance, which can reduce the overall reflection intensity, is certainly also useful for the purpose of improving the absorption efficiency.

In practical designs, 3D photonic crystals can be used to achieve changes of propagation angle on all incident directions and polarizations. In order to make use of the resonances, a complete photonic bandgap is not desired. Consequently, relatively simple structures, such as a simple cubic lattice with (100) surface termination, are sufficient for this application. The frequency range should be chosen so that at least one mode can be excited, for example by incident angles of 0°-30° in the high-dielectric material.

Moreover, the photonic crystal should possess sections of flat constant-frequency contours perpendicular to the surface. The band structure as well as the constant-frequency contours of a simple-cubic lattice of air spheres of radius 0.48α in Si have been calculated, and found that frequency regions (0.25-0.30)·2πc/α corresponding to the third, fourth and fifth bands and are sufficient for these criteria. For use at the Si bandgap 1 μm, the inventive design has a lattice constant α of roughly 250-300 nm, and is within the reach of current electron-beam or X-ray lithography.

Although the present invention has been shown and described with respect to several preferred embodiments thereof, various changes, omissions and additions to the form and detail thereof, may be made therein, without departing from the spirit and scope of the invention.

What is claimed is:

1. A solar cell comprising:
a photovoltaic material region;
a uniform anti-reflection coating that is positioned on said photovoltaic material region; and
a photonic crystal structure that that is positioned below the photovoltaic material region, said photonic crystal structure provides a medium to produce a plurality of spatial orientations of an incident light signal received by said solar cell so as to allow trapping of a selected frequency range of incident light in said solar cell.

2. The solar cell of claim 1, wherein said photovoltaic material region comprises silicon, or another indirect bandgap semiconductor

3. The solar cell of claim 1, wherein the diffractive component of said photonic crystal structure comprises holes of air or dielectric materials.

4. The solar cell of claim 1, wherein the reflective component of said photonic crystal structure comprises alternating layers of high and low index.

5. The solar cell of claim 1, wherein said photonic crystal structure comprises a 1D periodic dielectric structure with a reflector on the bottom.

6. The solar cell of claim 1, wherein said photonic crystal structure comprises a 2D periodic dielectric structure with a reflector on the bottom.

7. The solar cell of claim 1, wherein said photonic crystal structure comprises a 3D periodic dielectric structure with a reflector on the bottom.

8. The solar cell of claim 2, wherein the diffractive component of said photonic crystal structure comprises a periodically etched grating on a DBR.

9. A method of forming a solar cell comprising:
providing a photovoltaic material region;
forming a uniform anti-reflection coating that is positioned on said photovoltaic material region; and
forming a photonic crystal structure that that is positioned below the photovoltaic material region, said photonic crystal structure provides a medium to produce a plurality of spatial orientations of an incident light signal received by said solar cell so as to allow trapping of a selected frequency range of incident light in said solar cell.

10. The method of claim 9, wherein said photovoltaic material region comprises silicon, or another indirect bandgap semiconductor.

11. The method of claim 9, wherein the diffractive component of said photonic crystal structure comprises holes of air or dielectric materials.

12. The method of claim 9, wherein the reflective component of said photonic crystal structure comprises alternating layers of high and low index.

13. The method of claim 9, wherein said photonic crystal structure comprises a 1D periodic dielectric structure with a reflector on the bottom.

14. The method of claim 9, wherein said photonic crystal structure comprises a 2D periodic dielectric structure with a reflector on the bottom.

15. The method of claim 9, wherein said photonic crystal structure comprises a 3D photonic crystal structure with a reflector on the bottom.

16. The method of claim 10, wherein the diffractive component of said photonic crystal structure comprises a periodically etched grating on a DBR.

17. A method of trapping light in a solar cell comprising:
providing a photovoltaic material region;
forming a planar top surface;
positioning a uniform anti-reflection coating on top of the said photovoltaic material region; and
positioning a photonic crystal structure on said photovoltaic material region, said photonic crystal structure provides a medium to produce a plurality of spatial orientations of an incident light signal received by said solar cell so as to allow trapping of a selective frequency of incident light in said solar cell.

18. The method of claim 17, wherein said photovoltaic material region comprises silicon, or another indirect bandgap semiconductor.

19. The method of claim 17, wherein said photonic crystal structure comprises holes of air or dielectric.

20. The method of claim 17, wherein the reflective component of said photonic crystal structure comprises alternating layers of high and low index.

21. The method of claim 17, wherein said photonic crystal structure comprises a 1D periodic dielectric structure with a reflector on the bottom.

22. The method of claim 17, wherein said photonic crystal structure comprises a 2D periodic dielectric structure with a reflector on the bottom.

23. The method of claim 17, wherein said photonic crystal structure comprises a 3D periodic dielectric structure with a reflector on the bottom.

24. The method of claim 18, wherein the diffractive component of said photonic crystal structure comprises a periodically etched grating on a DBR.

25. A solar cell comprising:
a photovoltaic material region;
a planar top surface of said photovoltaic material region;
a uniform anti-reflection coating on top of said photovoltaic material region; and
a photonic crystal structure that surrounds a portion of said photovoltaic material region, said photonic crystal structure provides a medium to produce a plurality of spatial orientations of an incident light signal received by said solar cell so as to allow trapping of a selective frequency of incident light in said solar cell.

26. The solar cell of claim 25, wherein said photovoltaic material region comprises silicon or another indirect bandgap semiconductor

27. The solar cell of claim 25, wherein said photonic crystal structure comprises holes of air or dielectric materials.

28. The solar cell of claim 25, wherein the reflective component of said photonic crystal structure comprises alternating layers of high and low index.

29. The solar cell of claim 25, wherein said photonic crystal structure comprises a 1D periodic dielectric structure with a reflector on the bottom.

30. The solar cell of claim 25, wherein said photonic crystal structure comprises a 2D periodic dielectric structure with a reflector on the bottom.

31. The solar cell of claim 1, wherein said photonic crystal structure comprises a 3D periodic dielectric structure with a reflector on the bottom.

32. The solar cell of claim 26, wherein said photonic crystal structure comprises a periodically etched grating on a DBR.

33. A method of forming a solar cell comprising
forming a photovoltaic material region;
forming a planar surface on the top of said photovoltaic material region;
a uniform anti-reflection coating on top of said photovoltaic material region; and
forming a photonic crystal structure that only surrounds a portion of said photovoltaic material region, said photonic crystal structure provides a medium to produce a plurality of spatial orientations of an incident light signal received by said solar cell so as to allow trapping of a selective frequency of incident light in said solar cell.

34. The method of claim 33, wherein said photovoltaic material region comprises silicon or another indirect bandgap semiconductor.

35. The method of claim 33, wherein said photonic crystal structure comprises holes of air or another dielectric material.

36. The method of claim 33, wherein the reflective component of said photonic crystal structure comprises alternating layers of high and low index.

37. The method of claim 33, wherein said photonic crystal structure comprises a 1D periodic dielectric structure with a reflector on the bottom.

38. The method of claim 33, wherein said photonic crystal structure comprises a 2D periodic dielectric structure with a reflector on the bottom.

39. The method of claim 33, wherein said photonic crystal structure comprises a 3D periodic dielectric structure with a reflector on the bottom.

40. The method of claim 34, wherein the reflective component of said photonic crystal structure comprises a periodically etched grating on a DBR.
